(19) United States
(12) Patent Application Publication
(10) Pub. No.: US 2023/0063023 A1
(43) Pub. Date: Mar. 2, 2023

(54) SYSTEM AND METHOD FOR PREDICTING REMAINING USEFUL LIFE OF TRANSFORMER

(71) Applicant: Fortune Electric Co., Ltd., Taoyuan City (TW)

(72) Inventors: Guan-shiang Wang, Taoyuan City (TW); Jen-wen Chang, Taoyuan City (TW); CHIA-CHING LIN, Taoyuan City (TW)

(21) Appl. No.: 17/464,645

(22) Filed: Sep. 1, 2021

(51) Int. Cl. G01R 31/62; H01F 27/32; G06N 20/00

(52) U.S. Cl. CPC G01R 31/62; H01F 27/321; G06N 20/00

(57) ABSTRACT

A system and a method for predicting a remaining useful life of a transformer are provided. The system includes the transformer and a processing device. The transformer includes a liquid insulating material and a solid insulating material. The processing device is configured to establish, through a machine learning method, a life prediction model based on status data and corresponding life loss data of the liquid insulating material and the solid insulating material, and the processing device uses the life prediction model to predict the remaining useful life of the transformer based on operating data of the transformer.

### FIELD OF THE DISCLOSURE

The present disclosure relates to a system and a method for predicting a remaining useful life of an electric device, and more particularly to a system and a method for predicting a remaining useful life of a transformer.

### BACKGROUND OF THE DISCLOSURE

A power transformer is a very important piece of equipment in a power transmission and distribution system. The power transformer needs to withstand impacts of a high voltage, a large electric current, an operating temperature rise, an electromagnetic force, and a mechanical force for extended periods of time. Failure of the power transformer often causes massive power outages and other major losses. Therefore, how to maintain a normal operation of the power transformer and predict and prevent impending failures is a very important issue.

Large-sized power transformers in the domestic power transmission and distribution system are all oil-immersed power transformers, and insulation of said power transformers mainly depends on insulating materials, such as an insulating oil, an insulating paper, and a pressboard. After operating for a long period of time, the insulating material of the transformer will deteriorate due to influences from the external environment, internal electrical power and heat, and may even completely lose its insulating ability. Results from an analysis of domestic and foreign accidents show that most of transformer damages or failures are caused by deterioration of the insulating material. That is to say, a lifespan of the transformer is determined by the deterioration of the insulating material.

Therefore, if an actual deterioration state of the insulating material can be obtained, a likely remaining useful life of the transformer can be accurately predicted. However, technologies that are conventionally used (such as analyzing the gas in the insulating oil and furfural) fail to meet the requirements of being economical, fast, and reliable.

### SUMMARY OF THE DISCLOSURE

In response to the above-referenced technical inadequacies, the present disclosure provides a system and a method for predicting a remaining useful life of a transformer, and the system and the method have advantages of being accurate, convenient, fast, and economical.

In one aspect, the present disclosure provides a method for predicting a remaining useful life of a transformer. The method is executed by a processing device, and the transformer includes a liquid insulating material and a solid insulating material. The method for predicting the remaining useful life of the transformer includes the following steps: establishing, through a machine learning method, a life prediction model based on status data and corresponding life loss data of the liquid insulating material and the solid insulating material; obtaining operating data of the transformer; and using the life prediction model to predict the remaining useful life of the transformer based on the operating data.

In another aspect, the present disclosure provides a system for predicting a remaining useful life of a transformer. The system includes the transformer and a processing device. The transformer includes a liquid insulating material and a solid insulating material. The processing device is configured to execute the following steps: establishing, through a machine learning method, a life prediction model based on status data and corresponding life loss data of the liquid insulating material; obtaining operating data of the transformer; and using the life prediction model to predict the remaining useful life of the transformer based on the operating data.

Therefore, by virtue of “establishing, through the machine learning method, the life prediction model based on the status data and the corresponding life loss data thereof of the liquid insulating material and the solid insulating material” and “using the life prediction model to predict the remaining useful life of the transformer based on the operating data”, the system and the method provided by the present disclosure can take necessary measures (such as having the transformer insulation-protected) before a lifespan of the transformer ends, so as to extend the lifespan of the transformer and ensure safe and stable operation of the transformer.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram illustrating a usage of a system for predicting a remaining useful life of a transformer according to the present disclosure;

FIG. 2 is a structural diagram of the system for predicting the remaining useful life of the transformer according to a first embodiment of the present disclosure;

FIG. 3 is a flowchart of a method for predicting a remaining useful life of a transformer according to the present disclosure;

FIG. 4 shows a user interface of a processing device of the system for predicting the remaining useful life of the transformer according to the first embodiment of the present disclosure;

FIG. 5 is a structural diagram of the system for predicting the remaining useful life of the transformer according to a second embodiment of the present disclosure; and

FIG. 6 is a structural diagram of the system for predicting the remaining useful life of the transformer according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

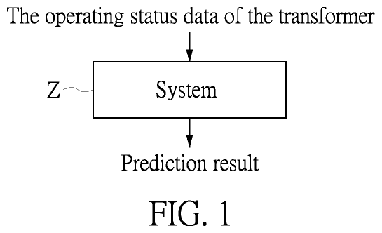

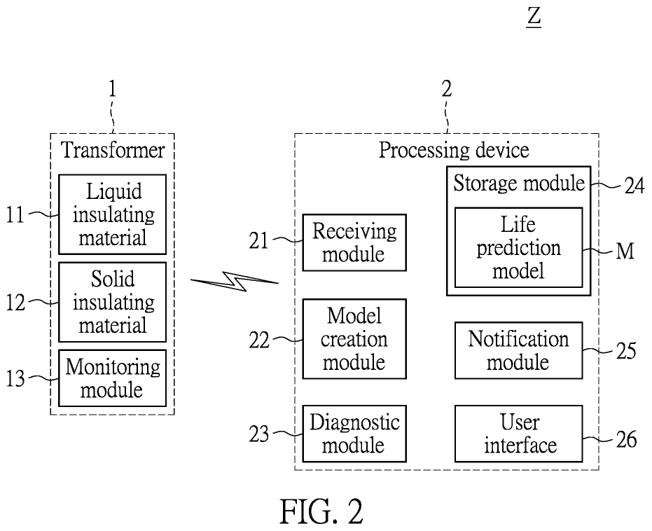

Referring to FIG. 1 and FIG. 2, FIG. 1 is a schematic diagram illustrating a usage of a system for predicting a remaining useful life of a transformer according to the present disclosure, and FIG. 2 is one of the structural diagrams of the system for predicting the remaining useful life of the transformer. As shown in FIG. 1 and FIG. 2, a system Z includes a transformer 1 and a processing device 2, and the processing device 2 is electrically connected to the transformer 1. In use, the processing device 2 can receive operating status data of the transformer 1, and then generate a prediction result including the remaining useful life of the transformer 1 based on the operating status data of the transformer 1.

In this embodiment, the transformer 1 is an oil-immersed transformer, and includes a liquid insulating material 11, one or more solid insulating materials 12, and a monitoring module 13. The liquid insulating material 11 is an insulating oil, the solid insulating material 12 is an insulating paper, and the monitoring module 13 is configured to monitor and obtain the operating data of the transformer 1. The monitoring module 13 mainly includes a temperature sensor and a moisture sensor, and may further include one or more gas sensors if required. The temperature sensor is used to monitor a temperature of the liquid insulating material 11 during an actual operation of the transformer 1, and the moisture sensor is used to monitor a moisture content of the solid insulating material 12 during the actual operation of the transformer 1. Further, the gas sensor is used to monitor a gas content of the liquid insulating material 11 during the actual operation of the transformer 1, such as oxygen (O₂), nitrogen (N₂), carbon monoxide (CO), carbon dioxide (CO₂), hydrogen (H₂), methane (CH₄), ethane (C₂H₆), ethylene (C₂H₄), and acetylene (C₂H₂). However, the aforementioned description is merely an example and is not meant to limit the scope of the present disclosure.

The processing device 2 can be a computer system or a server, and the processing device 2 maintains a wireless connection (such as WIFI wireless connection) with the transformer 1. The processing device 2 can include a receiving module 21, a model creation module 22, a diagnostic module 23, and a storage module 24, and these modules can be executed by a host computer or a processor of the server to realize their respective functions. In addition, the receiving module 21 is configured to receive the operating data of the transformer 1 obtained by the monitoring module 13. The model creation module 22 is configured to establish, through the machine learning method, a life prediction model M based on status data and their corresponding life loss data of the liquid insulating material 11 and the solid insulating material 12. The diagnostic module 23 is configured to estimate an actual state of insulation aging inside the transformer 1 based on the life prediction model M and the operating data of the transformer 1. In addition, the diagnostic module 23 can predict the remaining useful life (or lost life) of the transformer 1 based on the actual state of insulation aging inside the transformer 1. The storage module 24 is configured to store various types of required data, which include the operating data of the transformer 1, the status data of the liquid insulating material 11 and the solid insulating material 12, and their corresponding life loss data, etc. In addition, the life prediction model M created by the model creation module 22 can also be stored in the storage module 24.

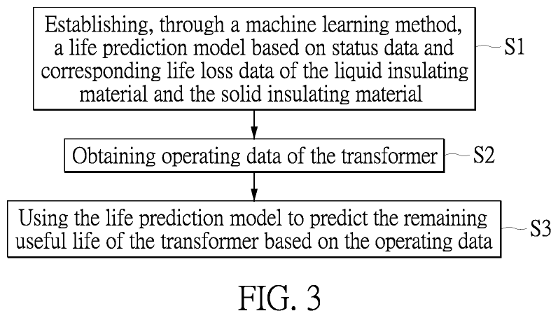

Referring to FIG. 3, the processing device 2 can execute the following steps: establishing, through a machine learning method, the life prediction model M based on the status data and the corresponding life loss data of the liquid insulating material 11 and the solid insulating material 12 (step S1); obtaining the operating data of the transformer 1 (step S2); and using the life prediction model M to predict the remaining useful life of the transformer 1 based on the operating data (step S3).

More specifically, based on the status data of the liquid insulating material 11 and the solid insulating material 12 and the corresponding life loss data thereof, the model creation module 22 uses the machine learning method to train and obtain the life prediction model M with a nonlinear function.

The machine learning method is a way to realize artificial intelligence, and a main purpose thereof is to analyze certain characteristics from various data, so as to predict a learning algorithm that may occur in the future. To predict the remaining useful life (or lost life) of the transformer 1, the machine learning method can learn the relevance or relationship between the status data (input parameters) and the life loss data (output parameters) of the liquid insulating material 11 and the solid insulating material 12, and verify the correctness of the life prediction model M by continuously utilizing the prediction results. Further, the life prediction model M can be optimized through repeated parameter adjustments.

In certain embodiments, the model creation module 22 can further use external research data to train the life prediction model M, so as to improve prediction accuracy. The external research data can be research or statistical data published in academic journals, which may have the same or similar characteristics or relationships with the status data of insulating materials.

In practice, the status data of the liquid insulating material 11 can be status data of a simulation test (a heat aging test), such as but not limited to temperature data of the insulating oil during simulation of the actual operation of the transformer 1. Similarly, the status data of the solid insulating material 12 can be simulated test status data, such as but not limited to moisture content data of the insulating paper during simulation of the actual operation of the transformer 1. It should be noted that when a moisture content of the insulating paper reaches a certain level (generally presented as a ratio of a mass of moisture contained in the insulating paper to a total mass of the insulating paper), a deterioration rate of the insulating paper will be increased. Therefore, in the present disclosure, the moisture content of the solid insulating material 12 is selected as the input parameter of the trained life prediction model M.

In addition, the life loss data can be obtained by measuring a tensile strength or a tensile index of the solid insulating material 12 (an insulating paper) that has undergone a simulation test. The reason is that cellulose will undergo a series of depolymerization reactions under influence of temperature, moisture, oxygen, and acidic substances in the oil, causing the insulating paper to become brittle (which also means that the tensile strength of the insulating paper will be reduced). Since the insulating paper cannot withstand stress generated by a breaking current, the insulation capacity of the transformer will be degraded. In other words, a lifespan of the transformer 1 is mostly determined by the state of the insulating paper.

The machine learning method used by the model creation module 22 can be a neural network algorithm using a back propagation network (BPN) architecture, and a training process is as follows:

(1) determining network parameters, which include a number of neurons in an input layer, a number of neurons in a hidden layer, a number of neurons in an output layer, a learning rate, and a number of learning times;

(2) randomly setting an initial weight value and an initial bias value of the network;

(3) entering the status data of the liquid insulating material 11 and the solid insulating material 12 for training purposes and the corresponding life loss data thereof;

(4) calculating an output value;

(5) calculating a gap between the output layer and the hidden layer;

(6) calculating a weighted correction value and a bias correction value between each layer;

(7) updating the weight value and the bias value between each layer; and

(8) repeating step (3) to step (7) until the network converges (that is, there are no more obvious errors) or reaches a set number of learning times.

Referring to FIG. 2, the processing device 2 can also include a notification module 25, which can also be executed by the host computer or the processor of the server to realize functions thereof. The notification module 25 is configured to send a reminder message when the diagnostic module 23 predicts that the remaining useful life (or lost life) of the transformer 1 is less than a set value, so that a transformer maintenance personnel can immediately take necessary measures, such as having the transformer 1 protected by insulation, so as to extend the lifespan of the transformer 1. The notification module 25 can allow the transformer maintenance personnel to receive the reminder message through a web page, an application program (APP), or an email, but is not limited to thereto.

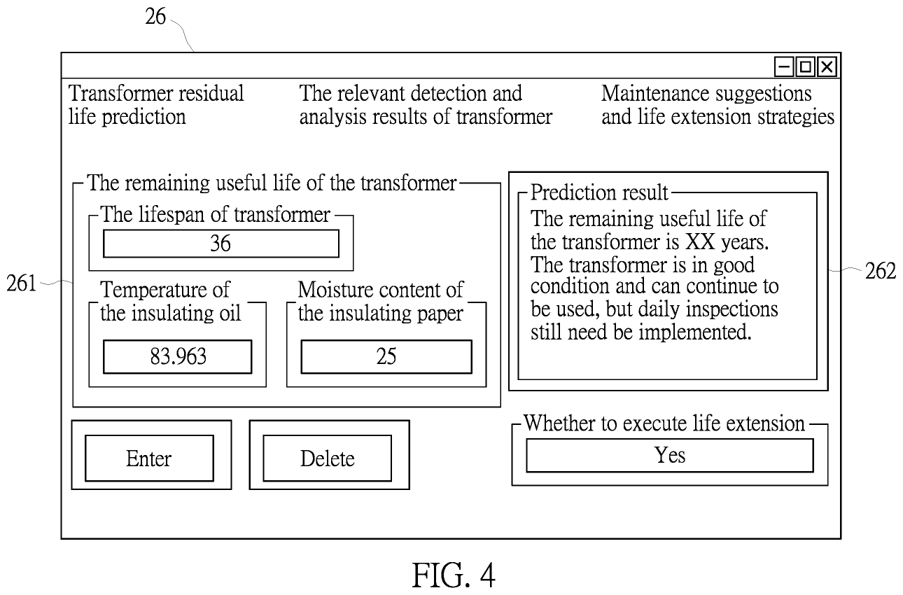

Referring to FIG. 4, the processing device 2 can also include a user interface 26. The user interface 26 can provide both the actual state of insulation aging inside the transformer 1 and the remaining useful life (or lost life) of the transformer 1 to a user, and the maintenance personnel can use the user interface 26 to realize the operation and setting of the processing device 2. In this embodiment, the user can enter the operating data of the transformer 1 in a data entry field 261 of the user interface 26 (such as the actual temperature of the insulating oil and the actual moisture content of the insulating paper), or alternatively, can further enter the lifespan of the transformer 1. Then, the prediction result including the remaining useful life of the transformer 1 can be obtained in a result output field 262 of the user interface 26. According to practical requirements, relevant detection and analysis results and maintenance suggestions of the transformer 1 can be further displayed on the user interface 26. The maintenance suggestions can include a time when consumables or parts are replaced or when the transformer 1 is expected to undergo routine maintenance. However, the aforementioned description is merely an example and is not meant to limit the scope of the present disclosure.

### Second Embodiment

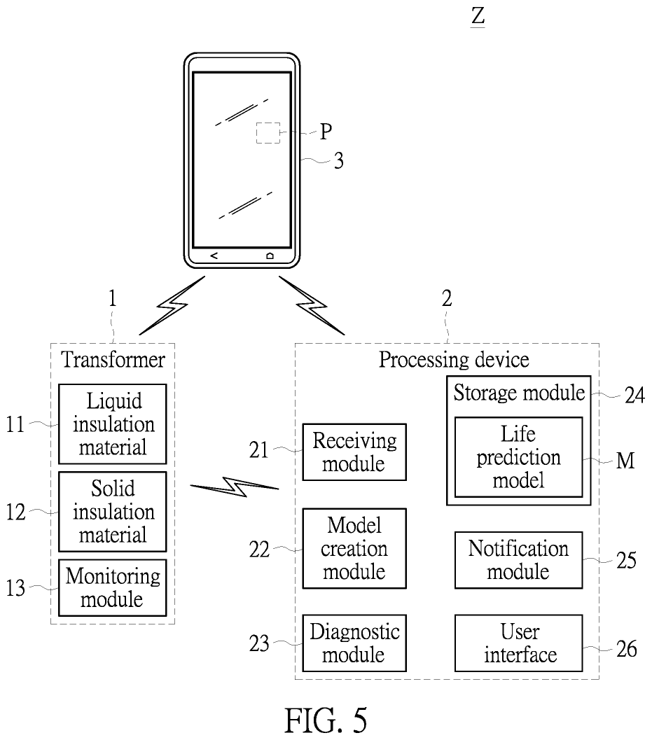

Reference is made to FIG. 5, which is another structural diagram of the system for predicting the remaining useful life of the transformer according to the present disclosure. Referring to FIG. 5, the system Z includes a transformer 1, a processing device 2, and at least one user mobile device 3 (such as a mobile phone), and the processing device 2, the transformer 1 and the user mobile device 3 are wirelessly connected to each other (such as WIFI wireless connection). In use, the processing device 2 can receive operating status data of the transformer 1, and then generate a prediction result including the remaining useful life of the transformer 1 based on the operating status data of the transformer 1. The user mobile device 3 can download an application program P. When the application program P is executed, the user interface 26 of the processing device 2 is displayed on a screen of the user mobile device 3. In this way, the user can obtain the prediction result including the remaining useful life of the transformer 1 through the user mobile device 3, and simultaneously obtain the relevant detection and analysis results and maintenance suggestions of the transformer 1 according to practical requirements. However, the aforementioned description is merely an example and is not meant to limit the scope of the present disclosure.

### Third Embodiment

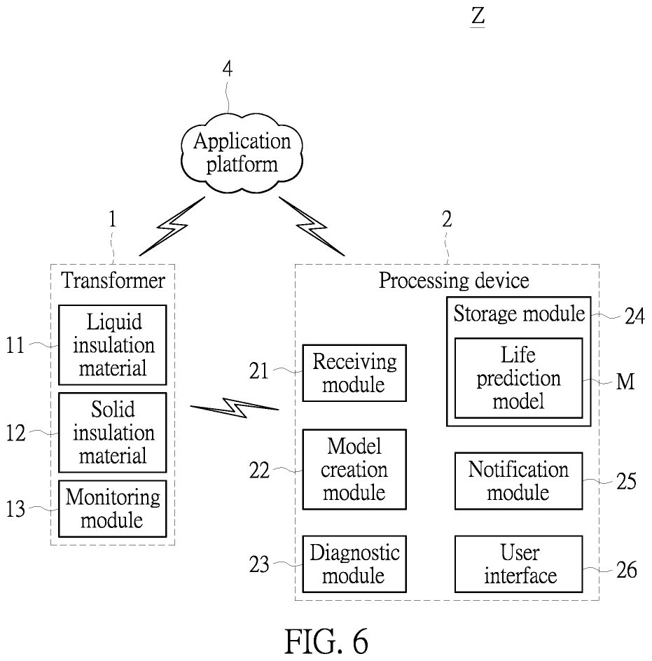

Reference is made to FIG. 6, which is yet another structural diagram of the system for predicting the remaining useful life of the transformer according to the present disclosure. Referring to FIG. 6, the system Z includes a transformer 1, a processing device 2, and at least one application platform 4 (such as an Internet of things (IoT) platform), and the processing device 2, the transformer 1 and the application platform 4 are wirelessly connected to each other (such as WIFI wireless connection). In use, the processing device 2 can receive operating status data of the transformer 1, and then generate a prediction result including the remaining useful life of the transformer 1 based on the operating status data of the transformer 1. The processing device 2 can send the prediction result of the remaining life of the transformer 1 (and, if required, the relevant detection and analysis results and maintenance suggestions of the transformer 1) to the application platform 4 for users to download and utilize. However, the aforementioned description is merely an example and is not meant to limit the scope of the present disclosure.

### Beneficial Effects of the Embodiments

In conclusion, by virtue of “establishing, through the machine learning method, the life prediction model based on the status data and the corresponding life loss data thereof of the liquid insulating material and the solid insulating material” and “using the life prediction model to predict the remaining useful life of the transformer based on the operating data”, the system and the method provided by the present disclosure can take necessary measures (such as having the transformer insulation-protected) before a lifespan of the transformer ends, so as to extend the lifespan of the transformer and ensure safe and stable operation of the transformer.

Furthermore, compared with conventional technologies, the system and the method provided by the present disclosure are more accurate, convenient, fast, and economical. By using the system and the method of the present disclosure, the relevant personnel can have a better grip of the actual state of insulation aging inside the transformer at any given time.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for predicting a remaining useful life of a transformer, wherein the method is executed by a processing device, and the transformer includes a liquid insulating material and a solid insulating material, the method comprising:
establishing, through a machine learning method, a life prediction model based on status data and corresponding life loss data of the liquid insulating material and the solid insulating material;
obtaining operating data of the transformer; and
using the life prediction model to predict the remaining useful life of the transformer based on the operating data.

2. The method according to claim 1, wherein the transformer is an oil-immersed transformer, the liquid insulating material is an insulating oil, and the solid insulating material is an insulating paper.

3. The method according to claim 2, wherein the status data of the liquid insulating material includes temperature data of the insulating oil in multiple simulated operating states of the transformer, and the status data of the solid insulating material includes moisture content data and tensile strength data of the insulating paper in the multiple simulated operating states of the transformer.

4. The method according to claim 3, wherein the operating data includes a lifespan of the transformer, the temperature data of the insulating oil in a real operating state of the transformer, and the moisture content data of the insulating paper in the real operating state of the transformer.

5. The method according to claim 1, wherein, before the step of predicting the remaining useful life of the transformer, the method further comprises: using external research data to train the life prediction model.

6. The method according to claim 1, wherein the machine learning method is a neural network algorithm of a back propagation network (BPN).

7. A system for predicting a remaining useful life of a transformer, comprising:
the transformer including a liquid insulating material and a solid insulating material; and
a processing device for executing following steps:
establishing, through a machine learning method, a life prediction model based on status data and corresponding life loss data of the liquid insulating material and the solid insulating material;
obtaining operating data of the transformer; and
using the life prediction model to predict the remaining useful life of the transformer based on the operating data.

8. The system according to claim 7, wherein the transformer is an oil-immersed transformer, the liquid insulating material is an insulating oil, and the solid insulating material is an insulating paper.

9. The system according to claim 8, wherein the status data of the liquid insulating material includes temperature data of the insulating oil in multiple simulated operating states of the transformer, and the status data of the solid insulating material includes moisture content data and tensile strength data of the insulating paper in the multiple simulated operating states of the transformer.

10. The system according to claim 9, wherein the operating data includes a lifespan of the transformer, the temperature data of the insulating oil in a real operating state of the transformer, and the moisture content data of the insulating paper in the real operating state of the transformer.

11. The system according to claim 8, wherein, before the processing device executes the step of predicting the remaining useful life of the transformer, the method further comprises: using external research data to train the life prediction model.

12. The system according to claim 8, wherein the machine learning method is a neural network algorithm of a back propagation network (BPN).
